(19) United States
(12) Patent Application Publication
(10) Pub. No.: US 2009/0268422 A1
(43) Pub. Date: Oct. 29, 2009

(54) SCALABLE ELECTRONIC PACKAGE ASSEMBLY FOR MEMORY DEVICES AND OTHER TERMINATED BUS STRUCTURES

(76) Inventors: Mark J. Bailey, Lake City, MN (US); Gerald K. Bartley, Rochester, MN (US); Richard B. Ericson, Rochester, MN (US); Wesley D. Martin, Elgin, MN (US); Benjamin W. Mashak, Rochester, MN (US); Trevor J. Timpane, Rochester, MN (US)

Correspondence Address: IBM CORPORATION, 3605 HIGHWAY 52 NORTH, DEPT 917, ROCHESTER, MN, 55901-7829, US

(21) Appl. No.: 12/111,791

(22) Filed: Apr. 29, 2008

(51) Int. Cl. H05K 1/11

(52) U.S. Cl. 361/803

(57) ABSTRACT

A scalable electronic package assembly for memory devices and other terminated bus structures is disclosed. The scalable electronic package assembly includes a first electronic carrier and a second electronic carrier. The first electronic carrier includes a first set of electronic devices controlled by a controller. The second electronic carrier includes a second set of electronic devices that are also controlled by the controller on the first electronic carrier. The second electronic carrier is electrically connected to the first electronic carrier via multiple solder columns. The second electronic carrier is physically stacked on top of the first electronic carrier via an insulator.

### BACKGROUND OF THE INVENTION

1. Technical Field

The present invention relates to electronic packages in general, and in particular to electronic package assemblies that are scalable.

2. Description of Related Art

Printed circuit boards are commonly utilized for interconnecting electronic components. Electronic packages are specialized electronic devices where multiple integrated circuits, semiconductor dies or other modules are packaged in such a way as to facilitate their use as a single integrated circuit. For a given product design having various electronic components mounted on printed circuit boards or as an electronic package, it is desirable to offer a memory size upgrade solution without a need to redesign the printed circuit boards or electronic package.

### SUMMARY OF THE INVENTION

In accordance with a preferred embodiment of the present invention, a scalable electronic package assembly includes a first electronic carrier and a second electronic carrier. The first electronic carrier includes a first set of electronic devices controlled by a controller. The second electronic carrier is electrically connected to the first electronic carrier via multiple solder columns. The second electronic carrier includes a second set of electronic devices that are also controlled by the controller located on the first electronic carrier. The second electronic carrier is physically stacked on top of the first electronic carrier via an insulator.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a diagram of a scalable electronic package having an electronic carrier in which a preferred embodiment of the present invention is incorporated;

FIG. 2 is a diagram of a scalable electronic package assembly having a second electronic carrier coupled to the electronic carrier from FIG. 1, in accordance with a preferred embodiment of the present invention; and

FIG. 3 is a diagram of a scalable electronic package assembly having a second electronic carrier coupled to the electronic carrier from FIG. 1, in accordance with an alternative embodiment of the present invention.

### DETAILED DESCRIPTION OF A PREFERRED EMBODIMENT

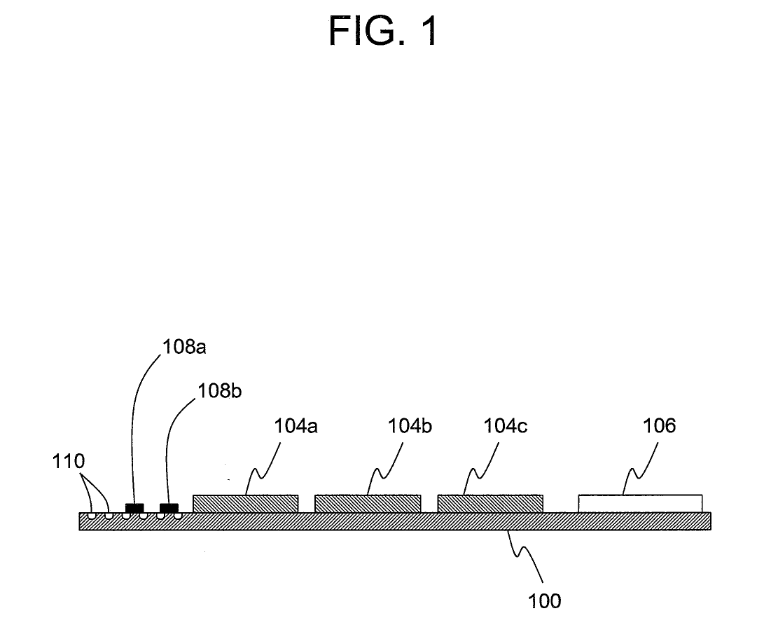

Referring now to the drawings and in particular to FIG. 1, there is depicted a diagram of a scalable electronic package (MCM) having an electronic carrier in which a preferred embodiment of the present invention can be incorporated. As is known in the art, the electronic carrier may include, for example, a printed circuit board (PCB), a ceramic substrate or a substrate on which modules are deposited using thin-film technology. As shown, an electronic carrier 100 is populated with memory devices 104a-104c and a memory controller 106 for controlling the signals between memory devices 104a-104c and other devices seeking to read data from or write data to memory devices 104a-104c, as is well known in the art. Memory devices 104a-104c can be dynamic random access memory devices or any other type of electronics devices. Memory controller 106 is electrically connected to memory devices 104a-104c via interconnects (not shown) located on as well as within electronic carrier 100. Interconnects preferably terminate in an array of pads 110 located on one end of electronic carrier 100. Multiple terminating resistors, such as terminating resistors 108a-108b, are electrically connected to some of pads 110 as needed to provide signal termination to the interconnects that terminate at pads 110. The interconnects and pads 110 can be “pre-wired” to accommodate the connection of a separate electronic carrier having additional memory devices to be controlled by memory controller 106.

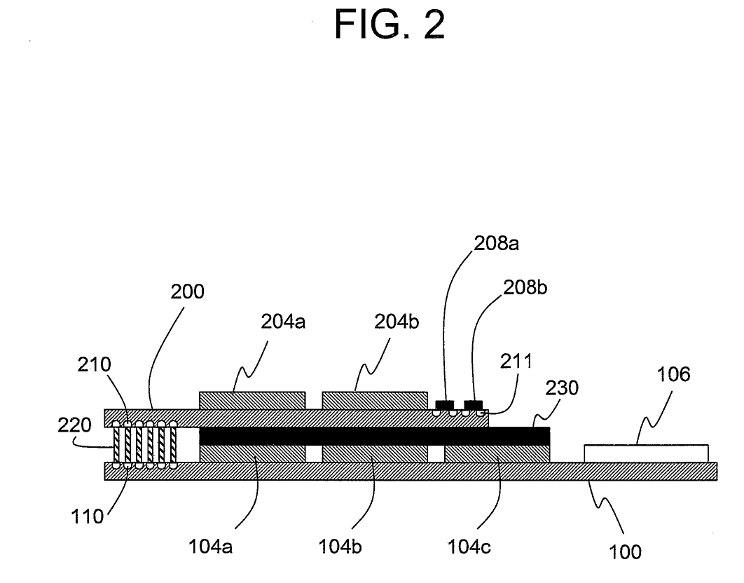

With reference now to FIG. 2, there is depicted a diagram of a second electronic carrier coupled to electronic carrier 100, in accordance with a preferred embodiment of the present invention. As shown, a electronic carrier 200 is stacked on top of electronic carrier 100 via an insulator 230. Terminating resistors 108a-108b (from FIG. 1) are removed from pads 110 on electronic carrier 100 so that second electronic carrier 200 may be electrically connected to electronic carrier 100 via solder columns 220 on pads 110. Specifically, solder columns 220 are connected between pads 110 on electronic carrier 100 and corresponding pads 210 on electronic carrier 200. Solder columns 220 electrically connect the interconnects on electronic carrier 100 to corresponding interconnects on electronic carrier 200. The interconnects on electronic carrier 200 are subsequently terminated by terminating resistors, such as terminating resistors 208a-208b, located on pads 211.

Similarly to electronic carrier 100, electronic carrier 200 is populated with memory devices, such as 204a-204b, that can also be controlled by memory controller 106 on electronic carrier 100 via the interconnects on electronic carrier 100 and electronic carrier 200. As a result, the memory capacity of electronic carrier 100 is expanded without increasing the footprint of electronic carrier 100 since electronic carrier 200 is stacked on top of electronic carrier 100. The increase in memory capacity of a electronic carrier without increasing its footprint is particularly important for product designs with limited mounting space. For example, if necessary, a third electronic carrier, which is similar to electronic carrier 200, can be stacked on top of electronic carrier 200 by relocating terminating resistors 208a-208b from electronic carrier 200 to the third electronic carrier.

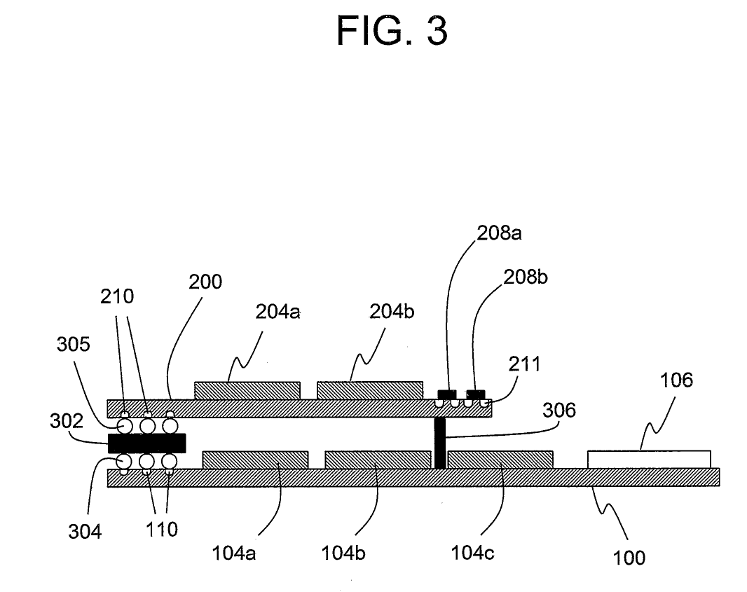

Referring now to FIG. 3, there is depicted a diagram of a scalable electronic package assembly having a second electronic carrier coupled to electronic carrier 100, in accordance with an alternative embodiment of the present invention. Instead of using solder columns 220, as shown in FIG. 2, an interposer carrier 302 is utilized to connect electronic carrier 100 to electronic carrier 200. Interposer carrier 302, which includes interconnects within, electrically connects electronic carrier 100 via solder balls 304 to electronic carrier 200 via solder balls 305. Solder balls 304 are connected between pads 110 on electronic carrier 100 and interposer carrier 302, and similarly, solder balls 305 are connected between interposer carrier 302 and corresponding pads 210 on electronic carrier 200. Solder balls 304 electrically connect the interconnects on electronic carrier 100 to corresponding interconnects on electronic carrier 200 via interposer carrier 302 and solder balls 305. The interconnects on electronic carrier 200 are terminated by terminating resistors, such as terminating resistors 208a-208h, mounted on pads 211.

The height of between electronic carrier 100 and electronic carrier 200 can be adjusted by changing the thickness of interposer carrier 302 and/or the size of solder balls 304 and 305. This arrangement is particularly useful for physical designs that are incapable of handling distances between electronic carrier 100 and electronic carrier 200 being too large to be reliably achieved via the usage of solder columns 220 shown in FIG. 2. Along with interposer carrier 302 and solder balls 304-305, a support structure 306 may be inserted between electronic carrier 100 and electronic carrier 200 to provide additional mechanical support between electronic carrier 100 and electronic carrier 200. Support structure 306 is preferably non-conductive electrically. In addition, interposer carrier 302 can be an impedance controlled connector for product designs that require additional space for heat-sinking devices on electronic carrier 100.

As has been described, the present invention provides an electronic package assembly that is scalable.

While the invention has been particularly shown and described with reference to a preferred embodiment, it will be understood by those skilled in the art that various changes in form and detail may be made therein without departing from the spirit and scope of the invention.

What is claimed is:

1. A scalable electronic package assembly comprising:
a first electronic carrier having a first set of electronic devices controlled by a controller;
an insulator; and
a second electronic carrier physically stacked on said first electronic carrier via said insulator, wherein said second electronic carrier is electrically connected to said first electronic carrier via a plurality of solder columns, wherein said second electronic carrier includes a second set of electronic devices also controlled by said controller on said first electronic carrier.

2. The scalable electronic package assembly of claim 1, wherein said second electronic carrier includes a plurality of terminating resistors.

3. The scalable electronic package assembly of claim 1, wherein said electronic devices are memory devices, and said controller is a memory controller.

4. The scalable electronic package assembly of claim 1, wherein said first electronic carrier is a printed circuit board.

5. The scalable electronic package assembly of claim 1, wherein said second electronic carrier is a printed circuit board.

6. The scalable electronic package assembly of claim 1, further comprising a third electronic carrier physically stacked on said second electronic carrier via a second insulator disposed between the third electronic carrier and the second electronic carrier, wherein said third electronic carrier is electrically connected to said first electronic carrier and said second electronic carrier via a plurality of solder columns, wherein said third electronic carrier includes a third set of electronic devices also controlled by said controller on said first electronic carrier.

7. The scalable electronic package assembly of claim 1, wherein said insulator further includes a mechanical support.

8. The scalable electronic package assembly of claim 1, wherein said insulator further includes a heat sink.

9. A scalable electronic package assembly comprising:
a first electronic carrier having a first set of electronic devices controlled by a controller;
an interposer carrier; and
a second electronic carrier physically stacked on said first electronic carrier via said interposer carrier, wherein said second electronic carrier is electrically connected to said first electronic carrier via said interposer carrier, wherein said second electronic carrier includes a second set of electronic devices also controlled by said controller on said first electronic carrier.

10. The scalable electronic package assembly of claim 9, wherein said second electronic carrier includes a plurality of terminating resistors.

11. The scalable electronic package assembly of claim 9, wherein said interposer carrier further includes a plurality of solder balls.

12. The scalable electronic package assembly of claim 9, wherein said electronic devices are memory devices, and said controller is a memory controller.

13. The scalable electronic package assembly of claim 9, wherein said first electronic carrier is a printed circuit board.

14. The scalable electronic package assembly of claim 9, wherein said second electronic carrier is a printed circuit board.

15. The scalable electronic package assembly of claim 9, wherein said interposer carrier is an impedance controlled connector.

16. The scalable electronic package assembly of claim 9, further comprising a third electronic carrier physically stacked on said second electronic carrier via a second interposer carrier disposed between said second electronic carrier and said third electronic carrier, wherein said third electronic carrier is electrically connected to said first electronic carrier and said second electronic carrier via said second interposer carrier, wherein said third electronic carrier includes a third set of electronic devices also controlled by said controller on said first electronic carrier.
